(19) United States
(12) Patent Application Publication
(10) Pub. No.: US 2015/0007868 A1
(43) Pub. Date: Jan. 8, 2015

(54) ENHANCED PHOTOVOLTAIC PERFORMANCE WITH MODIFIED BUS BAR REGION

(71) Applicant: TSMC Solar Ltd., Taichung City (TW)

(72) Inventor: Shih-Wei CHEN, Kaohsiung City (TW)

(21) Appl. No.: 13/936,428

(22) Filed: Jul. 8, 2013

(51) Int. Cl. H01L 31/052

(52) U.S. Cl. CPC H01L 31/0525
USPC 136/246; 438/72

(57) ABSTRACT

A photovoltaic device includes a planar photovoltaic panel including top electrode. A bus bar is affixed to the top electrode. A light scattering structure is affixed to the bus bar. The light scattering structure includes at least one reflecting surface arranged at an obtuse angle to the plane of the photovoltaic panel to reflect light onto the photovoltaic panel.

### BACKGROUND

This disclosure relates generally to photovoltaic cells and/or panels, and more particularly to photovoltaic cells and/or panels having a modified bus bar region with enhances their performance.

Photovoltaic cells and panels comprise flat structures that include a typically rectangular substrate, a back electrode formed on the substrate, a layer of photovoltaic absorber formed on the back electrode, a transparent buffer layer formed on the absorber layer, and a transparent top electrode formed on the buffer layer. Light shining on the absorber causes an electric current to flow between the back and top electrodes. The current is collected in a bus bar connected to the top electrode.

The amount of current produced by a photovoltaic panel of a particular structure is generally directly related to the area of the panel. Since the bus bar covers part of the panel, thereby shielding a part of the absorber from the light, the bus bar reduces the effective area of the panel, which reduces the panel's efficiency.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features can be arbitrarily increased or reduced for clarity of discussion.

FIGS. 1 is a front view of a photovoltaic panel in accordance with various embodiments of the present disclosure.

FIG. 2 is a section view taken along line 2-2 of FIG. 1.

FIG. 3 is section view of a second photovoltaic panel in accordance with various embodiments of the present disclosure.

FIG. 4 is section view of a third photovoltaic panel in accordance with various embodiments of the present disclosure.

FIG. 5 is a detail section view of a photovoltaic panel in accordance with various embodiments of the present disclosure.

FIG. 6 is a schematic view of a process for applying a bus bar and light scattering structure to photovoltaic panel in accordance with various embodiments of the present disclosure.

FIG. 7 is a schematic view of a process for applying a light scattering structure to a bus bar in accordance with various embodiments of the present disclosure.

FIG. 8 is a flow chart of a process for making a photovoltaic panel in accordance with various embodiments of the present disclosure.

FIG. 9 is a flow chart of a first process for applying a scattering structure to a bus bar in accordance with various embodiments of the present disclosure.

FIG. 10 is a flow chart of a second process for applying a scattering structure to a bus bar in accordance with various embodiments of the present disclosure.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning coupling and the like, such as “connected” and “interconnected,” refer to a relationship wherein devices or nodes are in direct or indirect electrical communication, unless expressly described otherwise.

It is understood that the following disclosure provides many different embodiments or examples for implementing different features of various embodiments. Specific examples of components and arrangements are described below to simplify the present disclosure. These are, of course, merely examples and are not intended to be limiting. The present disclosure may repeat reference numerals and/or letters in the various examples. This repetition is for the purpose of simplicity and clarity and does not in itself dictate a relationship between the various embodiments and/or configurations discussed.

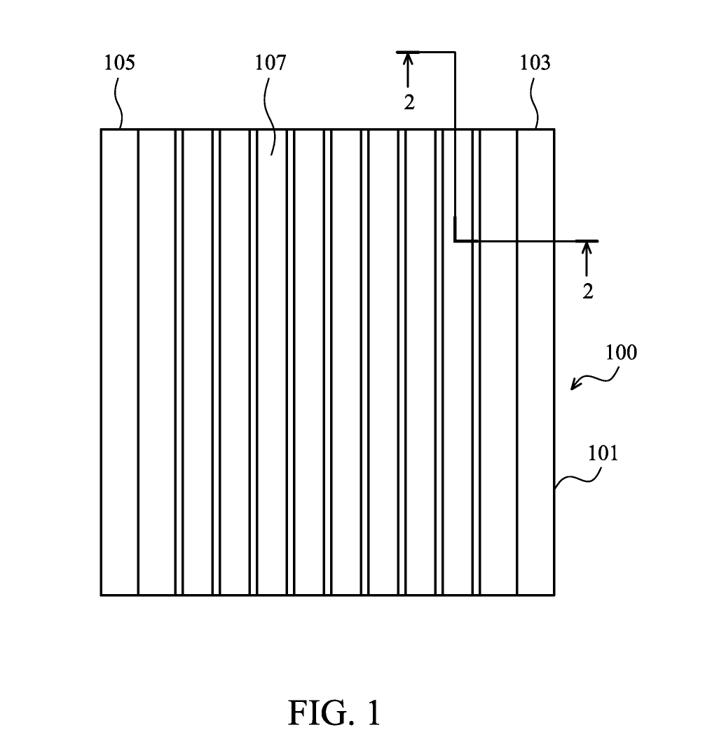

Referring now to the drawings, and first to FIG. 1, a photovoltaic device according to an embodiment of the present disclosure is designated generally by the numeral 100. Photovoltaic device 100 includes a planar, generally rectangular, panel 101 having bus bar and scattering structure combinations, designated generally by the numerals 103 and 105, according to various embodiments of the present disclosure affixed to opposite sides of its front surface 107.

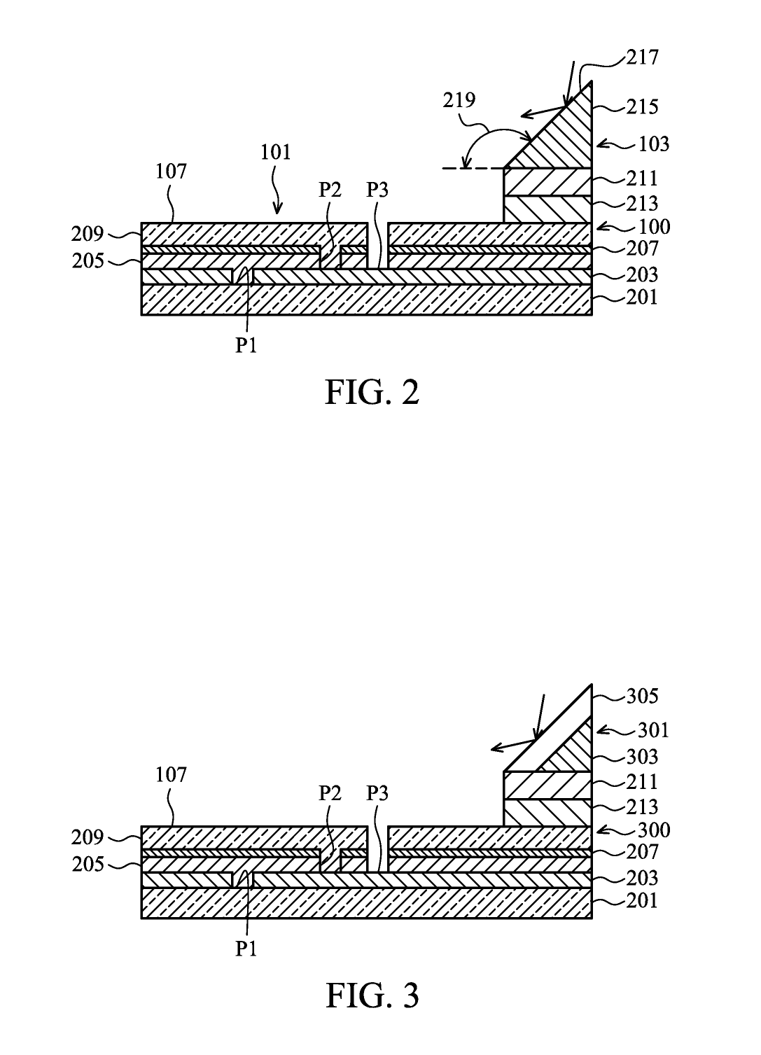

Referring now to FIG. 2, which is section view taken along line 2-2 of FIG. 1, panel 101 includes a substrate 201. Suitable materials for substrate 201 include, for example and without limitation, glass (such as soda lime glass), ceramic, metals such as thin sheets of stainless steel and aluminum, or polymers such as polyamides, polyethylene terephthalates, polyethylene naphthalates, polymeric hydrocarbons, cellulosic polymers, polycarbonates, polyethers, combinations thereof, or the like. A back electrode 203 of molybdenum, or the like, is formed over substrate 201. A first pattern P1 is cut in back electrode 203 down to substrate 201, typically using laser ablation.

An absorber layer 205 is formed over back electrode 203 and pattern Pl. In some embodiments, the absorber layer 205 is a copper indium gallium (di)selenide (CIGS), a I-III-VI2 semiconductor material composed of copper, indium, gallium, and selenium. CIGS is a solid solution of copper indium selenide (often abbreviated “CIS”) and copper gallium selenide. CIGS is a tetrahedrally bonded semiconductor, with the chalcopyrite crystal structure, and a bandgap varying continuously from about 1.0 eV (for copper indium selenide) to about 1.7 eV (for copper gallium selenide).

In some embodiments, the absorber layer 205 can comprise a p-type material. For example, absorber layer 205 can be a p-type chalcogenide material. In a further embodiment, the absorber layer 205 can be a CIGS Cu(In,Ga)Se2 material. In other embodiments, chalcogenide materials including, but not limited to, Cu(In,Ga)(Se, S)2 or “CIGSS,” CuInSe2, CuGaSe2, CuInS2, and Cu(In,Ga)S2. can be used as an absorber material. Suitable p-type dopants that can be used for forming absorber layer include without limitation boron (B) or other elements of group II or III of the periodic table. In another embodiment, the absorber layer can comprise an n-type material including, without limitation, cadmium sulfide (CdS).

A thin buffer layer 207 can be formed over absorber layer 205. Buffer layer 207 can be formed of a transparent metal oxide, such as vanadium oxide or molybdenum oxide. A second pattern P2 is cut, for example by mechanical scribing, in buffer layer 207 and absorber layer 205 down to back electrode 203. Then, a top electrode 209 of a transparent conducting oxide, such as zinc oxide or indium tin oxide, is formed on buffer layer 207. Finally, a third pattern P3 is cut, again for example by mechanical scribing, in top electrode 209, buffer layer 207, and absorber layer 205 down to back electrode 203.

Bus bar and scattering structure 103 (and 105) includes bus bar 211 comprising a conducting ribbon of copper or the like electrically connected to surface 107 of top electrode 209 by a strip 213 of solder or the like, and a light scattering structure 215 suitably adhered to bus bar 211. Light scattering structure 215 can be made of a reflective inorganic material such as a metal or a metal oxide. Light scattering structure includes a reflective surface 217 arranged to form an obtuse angle 219 with the plane formed by panel 100. Accordingly, reflective surface 217 reflects incident light that would otherwise be blocked by bus bar 211 onto absorber layer 203, thereby increasing the efficiency of panel 100.

FIG. 3 illustrates a section view of a photovoltaic panel 300 according to embodiments of the present disclosure including a second light scattering structure 301. Like photovoltaic panel 100, photovoltaic panel 300 includes a substrate 201. A back electrode 203 of molybdenum, or the like, is formed over substrate 201. A first pattern P1 is cut in back electrode 203 down to substrate 201. An absorber layer 205 is formed over back electrode 203 and pattern Pl. A thin buffer layer 207 can be formed over absorber layer 205. A second pattern P2 is cut in buffer layer 207 and absorber layer 205 down to back electrode 203. Then, a top electrode 209 of a transparent conducting oxide is formed on buffer layer 207. Finally, a third pattern P3 is cut in in top electrode 209, buffer layer 207 and absorber layer 205 down to back electrode 203. A bus bar 211 comprising a conducting ribbon of copper or the like is electrically connected to surface 107 of top electrode 209 by a strip 213 of solder or the like.

Light scattering structure 301 includes a triangular cross-section support 303 adhered to bus bar 211. Support 303 can be made of a metal, metal oxide, or other suitable supporting material. Light scattering structure 301 includes a strip 305 of phosphorescent material adhered to support 303 and bus bar 211. In addition to reflecting incident light onto absorber layer 205, phosphorescent material of strip 305 absorbs shorter wavelength light and emits longer wavelength light, some of which is directed onto absorber layer 205. Strip 305 can comprise an organic phosphorescent material such as Y₃Al₅O₁₂; Ce,Y₂SiO_{5;} Ce,InBO₃; or Tb, MgWO₄.

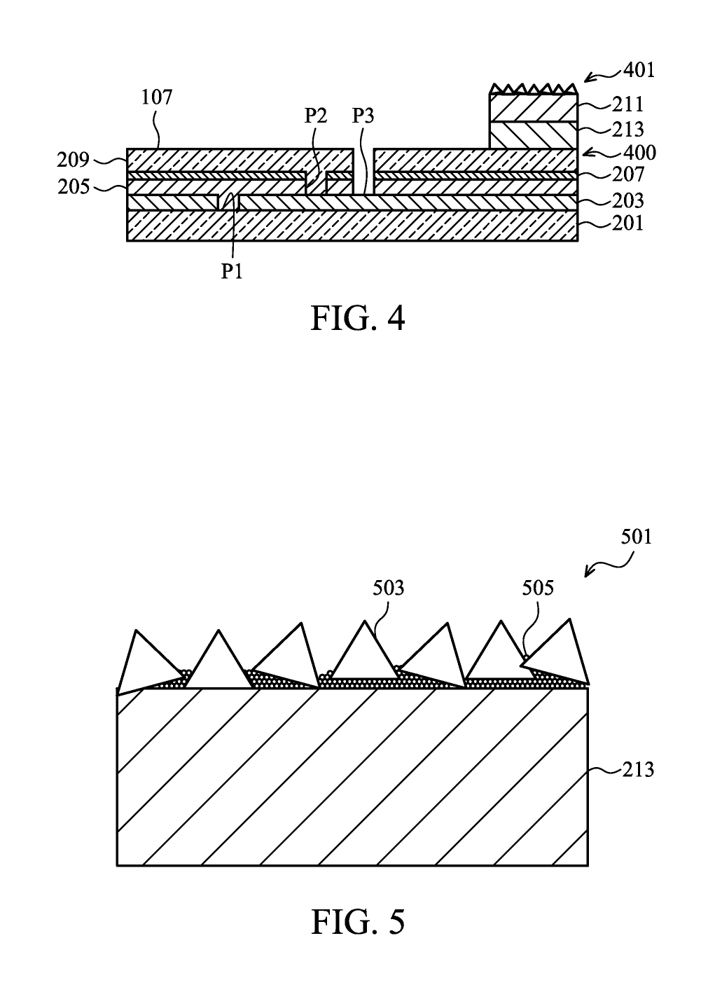

FIG. 4 illustrates a section view of a photovoltaic panel 400 according to some embodiments of the present disclosure including a third light scattering structure 401. Like photovoltaic panels 100 and 300, photovoltaic panel 400 includes a substrate 201. A back electrode 203 of molybdenum, or the like, is formed over substrate 201. A first pattern P1 is cut in back electrode 203 down to substrate 201. An absorber layer 205 is formed over back electrode 203 and pattern Pl. A thin buffer layer 207 can be formed over absorber layer 205. A second pattern P2 is cut in buffer layer 207 and absorber layer 205 down to back electrode 203. Then, a top electrode 209 of a transparent conducting oxide is formed on buffer layer 207. Finally, a third pattern P3 is cut in in top electrode 209, buffer layer 207 and absorber layer 205 down to back electrode 203. A bus bar 211 comprising a conducting ribbon of copper or the like is electrically connected to surface 107 of top electrode 209 by a strip 213 of solder or the like.

Light scattering structure 401 includes a plurality of reflective particles deposited on and adhered to bus bar 211. As generally represented by triangles, each particle includes reflective facets adapted to reflect incident light that would otherwise be blocked by bus bar 211 toward absorber layer 205. The particles of light scattering structure 401 can comprise a metal, such as molybdenum, or a metal oxide, such as aluminum oxide (Al₂O₃).

FIG. 5 is a detail view of a light scattering structure 501 according to embodiments of the present disclosure. Light scattering structure 501 includes a plurality of reflective inorganic particles 503, represented by triangles, and organic particles 505, represented by circles, distributed the surface of bus bar 213. Inorganic particles 503 are faceted and they include reflective surface to direct incident light. Organic particles 505 can be phosphorescent to absorb short wavelength light and emit longer wavelength light.

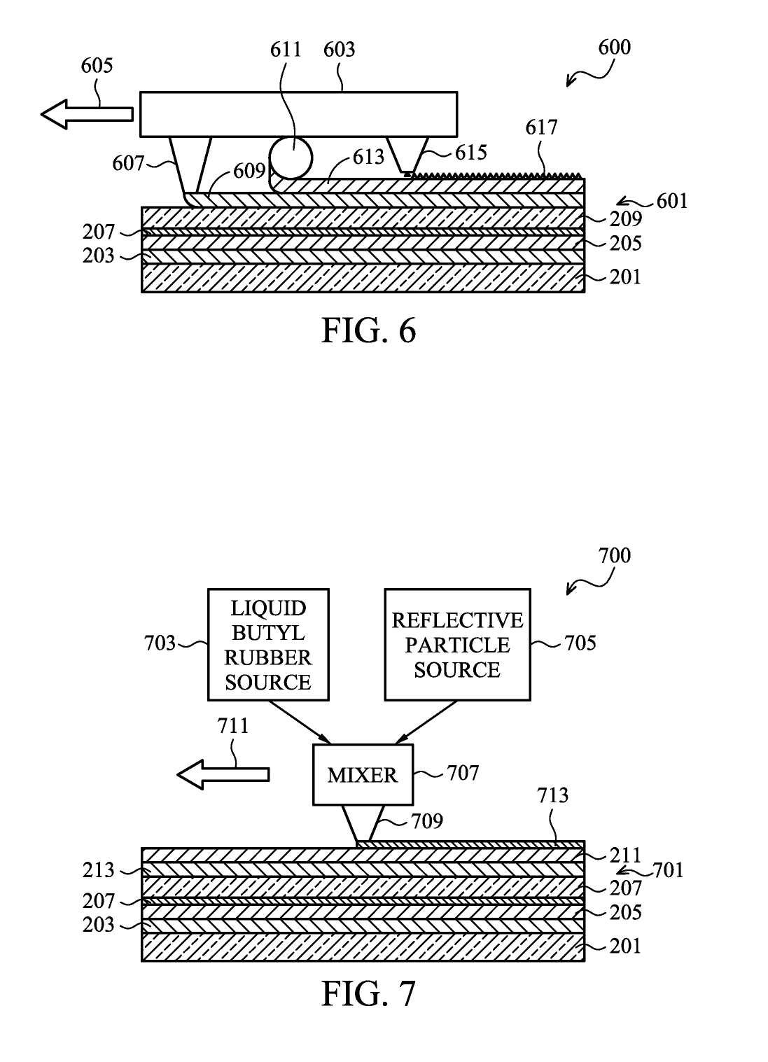

FIG. 6 is a schematic view of a system 600 for applying a bus bar and a light scattering structure to a photovoltaic panel 601, according to some embodiments of the present disclosure. Photovoltaic panel 600 includes a substrate 201. A back electrode 203 is formed over substrate 201. An absorber layer 205 is formed over back electrode 203. A thin buffer layer 207 can be formed over absorber layer 205. Then, a top electrode 209 of a transparent conducting oxide is formed on buffer layer 207.

System 600 includes a carriage 603 positioned above photovoltaic panel 601 and adapted to move with respect to photovoltaic panel 601 in the direction of arrow 605. Carriage 603 carries a solder application unit 607, which applies a strip of molten solder 609 to top electrode 209, and reel 611, which lays a ribbon 613 of copper on solder strip 609 to form a bus bar. Carriage 603 finally carries a print head 615 which applies a layer or reflective particles 617 to copper ribbon 613, thereby forming a light scattering structure.

FIG. 7 is a schematic view of a system 700 for applying a light scattering structure to a photovoltaic panel 700, according to embodiments of the present disclosure. Photovoltaic panel 00 includes a substrate 201. A back electrode 203 is formed over substrate 201. An absorber layer 205 is formed over back electrode 203. A thin buffer layer 207 can be formed over absorber layer 205. Then, a top electrode 209 of a transparent conducting oxide is formed on buffer layer 207. A ribbon 211 of a conductor such as copper is adhered to top electrode 209 by a layer of solder 213 to form a bus bar.

System 700 includes a liquid butyl rubber source 703 and a reflective particle source 705, which are connected to supply liquid butyl rubber, which acts as binder, and reflective particles, respectively, to a mixer 707, which mixes the liquid butyl rubber and reflective particles. A nozzle 709 receives the mixture of liquid butyl rubber and reflective particles from mixer 707. System 700 is adapted to move with respect to photovoltaic panel 701 in the direction of arrow 711, whereby nozzle 709 applies a layer 713 of the mixture of liquid butyl rubber and reflective particles to ribbon 211 to form a light scattering structure.

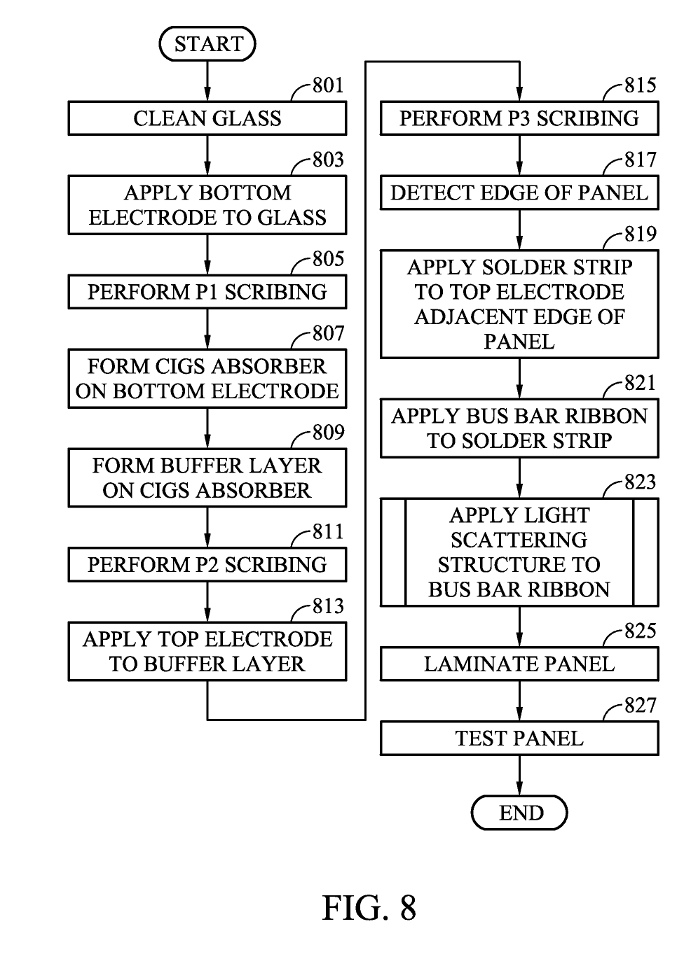

FIG. 8 is a flowchart of a process for making photovoltaic panels according to embodiments of the present disclosure. The glass forming the substrate is cleaned, at block 801. Then, the bottom electrode is applied to the glass, at block 803, and the process performs P1 scribing of the back electrode, as described above, at block 805. The process then forms the CIGS absorber on the bottom electrode, as indicated at block 807. A buffer layer can be formed on the CIGS absorber, at block 809. After the step of forming the buffer layer, the process performs P2 scribing of the CIGS absorber and the buffer layer, as indicated at block 811. After performing P2 scribing, the process applies the top electrode to the buffer layer, at block 813. Then, the process performs P3 scribing of the top electrode, the buffer layer, and the CIGS absorber, as indicated at block 815.

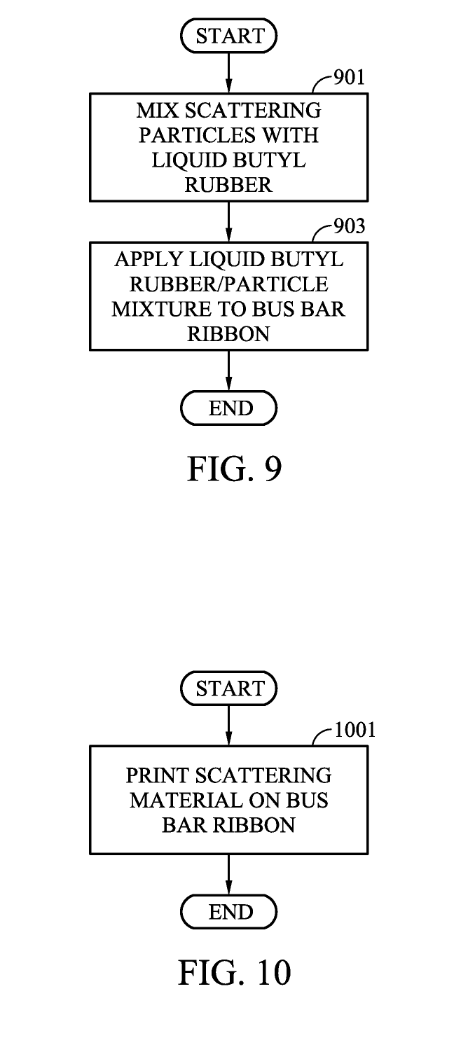

After applying the foregoing layers and performing the scribing operations, the process detects an edge of the thus formed panel, at block 817, and applies a solder strip to the top electrode adjacent the detected edge of the panel, as indicated at block 819. Then, the process applies the bus bar ribbon to the solder strip, at block 821. After forming the bus bar, the process applies the light scattering structure to the bus bar ribbon, as indicated generally at block 823 and described in detail with reference to FIGS. 9 and 10. After applying the light scattering structure, the process laminates the panel, at block 825, and tests the panel, at block 827.

FIGS. 9 and 10 are flowcharts of processes for applying the light scattering structure to the bus bar ribbon according to embodiments of the present disclosure. In FIG. 9, the process mixes scattering particles with liquid butyl rubber, at block 901. Then, the process applies a layer of the liquid butyl rubber/scattering particle mixture to the bus bar ribbon, at block 903. In FIG. 10, the process prints scattering material on the bus bar ribbon, as indicated at block 1001.

In some embodiments, a photovoltaic device comprises: a planar photovoltaic panel including top electrode; a bus bar affixed to the top electrode; and, a light scattering structure affixed to the bus bar, the light scattering structure including at least one reflecting surface arranged at an obtuse angle to the plane of the photovoltaic panel to reflect light onto the photovoltaic panel.

In some embodiments, the light scattering structure includes a plurality of light reflecting particles affixed to the bus bar.

In some embodiments, the light reflecting particles comprise an inorganic material.

In some embodiments, the light scattering structure includes a plurality of organic particles mixed with the inorganic particles, the organic particles absorbing light of a first wavelength and emitting light of a second wavelength.

In some embodiments, the light reflecting particles comprise an organic material.

In some embodiments, the light reflecting particles comprise an organic material.

In some embodiments, the organic particles absorb light of a first wavelength and emit light of a second wavelength.

In some embodiments, the light scattering structure comprises: a plurality of light reflecting particles in a binder adhered to the bus bar.

In some embodiments, the binder comprises butyl rubber.

In some embodiments, the at least one reflecting surface is formed by a plurality of light reflecting particles affixed to the bus bar.

In some embodiments, the light reflecting particles comprise an inorganic material.

In some embodiments, the photovoltaic device includes a plurality of organic particles mixed with the phosphorescent particles, the phosphorescent particles absorbing light of a first wavelength and emitting light of a second wavelength.

In some embodiments, the organic particles absorb light of a first wavelength and emit light of a second wavelength.

In some embodiments, a method of making a photovoltaic device, comprises: applying a first conducting layer to a substrate; forming an absorber layer on the first conducting layer; forming a buffer layer on the absorber layer; forming a second conducting layer on the buffer layer; affixing a bus bar to the second conducting layer; affixing a light scattering structure to the bus bar, the light scattering structure including at least one reflecting surface arranged at an obtuse angle to the plane of the photovoltaic panel to reflect light onto the photovoltaic panel.

In some embodiments, the light scattering structure includes a plurality of light reflecting particles.

In some embodiments, the light reflecting particles comprise an inorganic material.

In some embodiments, the light scattering structure includes a plurality of phosphorescent particles mixed with the inorganic particles, the phosphorescent particles absorbing light of a first wavelength and emitting light of a second wavelength.

In some embodiments, affixing the light scattering structure to the bus bar includes: printing a plurality of light reflecting particles on the bus bar.

In some embodiments, affixing the light scattering structure to the bus bar includes: forming a mixture of light reflecting particles and a binder; and, applying the mixture of light reflecting particles and a binder to the bus bar

In some embodiments, a photovoltaic device, which comprises: a planar photovoltaic panel including top electrode; a bus bar affixed to the top electrode; and, a light scattering structure affixed to the bus bar, the light scattering structure including a plurality of particles that absorb light of a first wavelength and emit light of a second wavelength, wherein the particles are arranged to direct emitted light of the second wavelength onto top electrode.

The methods and system described herein may be at least partially embodied in the form of computer-implemented processes and apparatus for practicing those processes. The disclosed methods may also be at least partially embodied in the form of tangible, non-transient machine readable storage media encoded with computer program code. The media may include, for example, RAMs, ROMs, CD-ROMs, DVD-ROMs, BD-ROMs, hard disk drives, flash memories, or any other non-transient machine-readable storage medium, wherein, when the computer program code is loaded into and executed by a computer, the computer becomes an apparatus for practicing the method. The methods may also be at least partially embodied in the form of a computer into which computer program code is loaded and/or executed, such that, the computer becomes a special purpose computer for practicing the methods. When implemented on a general-purpose processor, the computer program code segments configure the processor to create specific logic circuits. The methods may alternatively be at least partially embodied in a digital signal processor formed of application specific integrated circuits for performing the methods.

The above-described embodiments, are merely possible examples of implementations, merely set forth for a clear understanding of the principles of the disclosure. Many variations and modifications can be made to the above-described embodiments of the disclosure without departing substantially from the spirit and principles of the disclosure. All such modifications and variations are intended to be included herein within the scope of this disclosure and the present disclosure and protected by the following claims.

Further, the foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

While preferred embodiments of the present subject matter have been described, it is to be understood that the embodiments described are illustrative only and that the appended claims shall be accorded a full range of equivalents, many variations and modifications naturally occurring to those of skill in the art from a perusal hereof.

What is claimed is:

1. A photovoltaic device, which comprises:
a planar photovoltaic panel including a top electrode;
a bus bar affixed to the top electrode; and,
a light scattering structure affixed to the bus bar, the light scattering structure including at least one reflecting surface arranged at an obtuse angle to the plane of the photovoltaic panel to reflect light onto the photovoltaic panel.

2. The photovoltaic device as claimed in claim 1, wherein the light scattering structure includes a plurality of light reflecting particles affixed to the bus bar.

3. The photovoltaic device as claimed in claim 2, wherein the light reflecting particles comprise an inorganic material.

4. The photovoltaic device as claimed in claim 3, wherein the light scattering structure includes a plurality of organic particles mixed with the inorganic particles, the organic particles absorbing light of a first wavelength and emitting light of a second wavelength.

5. The photovoltaic device as claimed in claim 2, wherein the light reflecting particles comprise an organic material.

6. The photovoltaic device as claimed in claim 5, wherein the organic particles absorb light of a first wavelength and emit light of a second wavelength.

7. The photovoltaic device as claimed in claim 1, wherein the light scattering structure comprises:
a plurality of light reflecting particles in a binder adhered to the bus bar.

8. The photovoltaic device as claimed in claim 7, wherein the binder comprises butyl rubber.

9. The photovoltaic device as claimed in claim 1, wherein the at least one reflecting surface is formed by a plurality of light reflecting particles affixed to the bus bar.

10. The photovoltaic device as claimed in claim 9, wherein the light reflecting particles comprise an inorganic material.

11. The photovoltaic device as claimed in claim 10, including a plurality of organic particles mixed with the phosphorescent particles, the phosphorescent particles absorbing light of a first wavelength and emitting light of a second wavelength.

12. The photovoltaic device as claimed in claim 9, wherein the light reflecting particles comprise an organic material.

13. The photovoltaic device as claimed in claim 12, wherein the organic particles absorb light of a first wavelength and emit light of a second wavelength.

14. A method of making a photovoltaic device, which comprises:
applying a first conducting layer to a substrate;
forming an absorber layer on the first conducting layer;
forming a buffer layer on the absorber layer;
forming a second conducting layer on the buffer layer;
affixing a bus bar to the second conducting layer;
affixing a light scattering structure to the bus bar, the light scattering structure including at least one reflecting surface arranged at an obtuse angle to the plane of the photovoltaic panel to reflect light onto the photovoltaic panel.

15. The method as claimed in claim 14, wherein the light scattering structure includes a plurality of light reflecting particles.

16. The method as claimed in claim 15, wherein the light reflecting particles comprise an inorganic material.

17. The method as claimed in claim 16, wherein the light scattering structure includes a plurality of phosphorescent particles mixed with the inorganic particles, the phosphorescent particles absorbing light of a first wavelength and emitting light of a second wavelength.

18. The method as claimed in claim 14, wherein affixing the light scattering structure to the bus bar includes:
printing a plurality of light reflecting particles on the bus bar.

19. The method as claimed in claim 14, wherein affixing the light scattering structure to the bus bar includes:
forming a mixture of light reflecting particles and a binder; and, applying the mixture of light reflecting particles and a binder to the bus bar.

20. A photovoltaic device, which comprises:
a planar photovoltaic panel including top electrode;
a bus bar affixed to the top electrode; and,
a light scattering structure affixed to the bus bar, the light scattering structure including a plurality of particles that absorb light of a first wavelength and emit light of a second wavelength, wherein the particles are arranged to direct emitted light of the second wavelength onto top electrode.
